(19) United States
(12) Patent Application Publication
(10) Pub. No.: US 2026/0050029 A1
(43) Pub. Date: Feb. 19, 2026

(54) DIE LEVEL TESTING OF VIAS SYSTEMS AND METHODS

(71) Applicant: pSemi Corporation, San Diego, CA (US)

(72) Inventors: Shishir Ray, San Diego, CA (US); Arpita Moghe Chadha, San Diego, CA (US); Saloni Chaurasia, Leander, TX (US); Panglijen Candra, San Diego, CA (US)

(21) Appl. No.: 18/807,872

(22) Filed: Aug. 16, 2024

(51) Int. Cl. G01R 31/28

(52) U.S. Cl. CPC G01R 31/2884; G01R 31/2853; G01R 31/2894

(57) ABSTRACT

Systems and methods for using a design for manufacturing (DFM) structure to detect an open via. The DFM structure comprises a resistor, one or more vias between a first pin and a second pin, and a transistor. A voltage from a voltage source is applied to the DFM structure that causes a current to flow across the resistor, the one or more vias and the transistor, such that the value of the current indicates an open or closed via.

### TECHNICAL FIELD

The disclosure generally relates to identifying a defective die, and more specifically to detecting an open via in a die using design for manufacturability structure.

### BACKGROUND

A die is a portion of a wafer that includes an integrated circuit. A wafer may include multiple dies. Conventionally the integrated circuit in each die is tested using an ink out process. In this process, the integrated circuit is tested using electrical testing, such as circuit probe or wafer sort testing. The defective dies, which may include bad or failing integrated circuits are marked with ink on the wafer, or are recorded in a log file or a digital wafer file that represents a location of the dies in the wafer.

Some defective or failing dies may include one or more open vias. Open vias may be detected using a scanning acoustic microscopy or C-SAM. Using C-SAM, however, is not production friendly because it is time consuming. The C-SAM also does not accurately detect all open vias. Rather it averages an array of vias, such as 20 vias, to determine whether one or more vias are open. Additionally, because dies with open vias are known to occur at a wafer age, a conventional approach typically blanket rejects dies at a wafer edge. The blanket rejection of dies, however, impacts a die yield of a wafer because it over-rejects dies and discards good dies as a result.

### BRIEF DESCRIPTION OF THE DRAWINGS

FIG. 1A is an exemplary diagram illustrating a wafer, according to some embodiments.

FIG. 1B is an exemplary diagram of a digital wafer file, according to some embodiments.

FIG. 2 is a diagram illustrating a digital wafer map representing good and defective dies, according to some embodiments.

FIGS. 3A-C are diagrams of an open via, according to some embodiments.

FIG. 4 is a diagram of a DFM structure for detecting an open via, according to some embodiments.

FIG. 5 is a block diagram of a test multiplexor in an integrated circuit of a die, according to some embodiment.

FIG. 6 is a flowchart of a method for generating a DFM structure in a die, according to some embodiments.

FIG. 7 is a flowchart of a method for identifying a defective die using a DFM structure, according to some embodiments.

Embodiments of the disclosure and their advantages are best understood by referring to the detailed description that follows. It should be appreciated that like reference numerals are used to identify like elements illustrated in one or more of the figures, wherein showings therein are for purposes of illustrating embodiments of the disclosure and not for purposes of limiting the same.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

A via is an electrical connection between two or more layers in an integrated circuit. A via may be a vertical hole through two or more layers in the integrated circuit that is filled with a conducive material, such as tungsten or copper. The via may pass signals or power vertically through different layers of the integrated circuit.

There may be different types of vias in the integrated circuit. A through hole is a via that passes through all layers of the integrated circuit. A blind via passes from a top or bottom layer to another layer in the integrated circuit. A buried via passes through one or more layers that are internal to the integrated circuit.

An open via is a via that is left unconnected to another layer or is left unsealed. Open vias may lead to integrated circuit failures and loss of dies. Moreover, open vias are typically observed at a wafer edge.

A design for manufacturing (DFM) structure may be used to augment or enhance insight into an integrated circuit manufacturing process. The DFM structure may be included in an integrated circuit and may be located within a process control monitor (PCM) cell of the integrated circuit. The DFM structure may identify an open via in the integrated circuit. The DFM structures allow for a PCM cell monitoring of a 3D-IC DBI (Direct Bond Interconnect)/UTM at a wafer edge, and help screen failures during sort. This significantly improves granularity for detecting damaged or failing die at a wafer edge, which, in turn, improves the yield of a wafer.

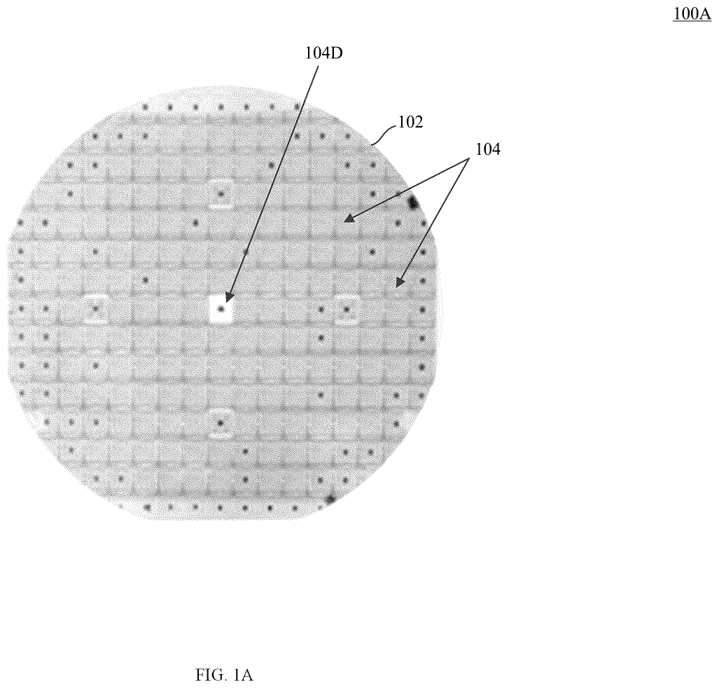

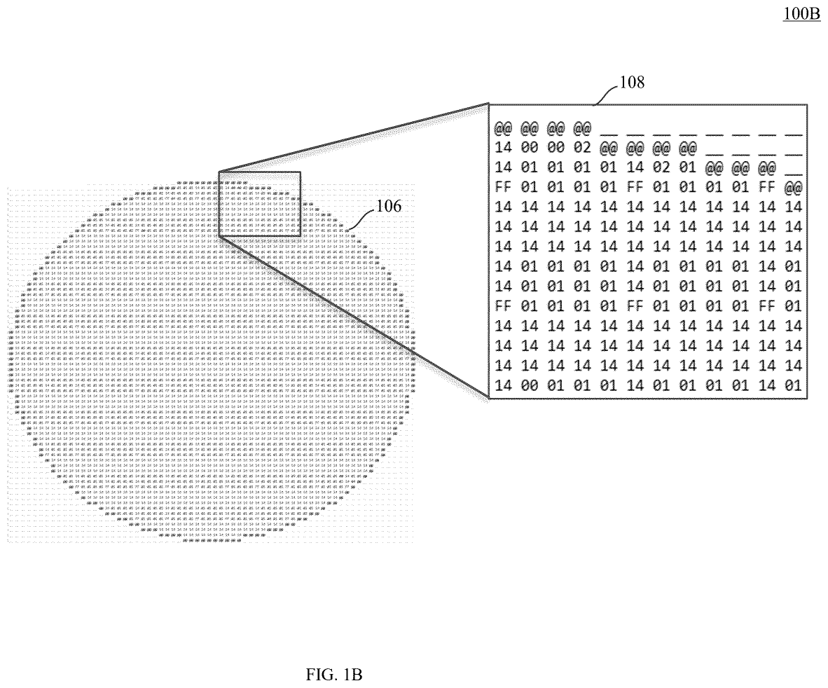

FIG. 1A is an exemplary diagram 100A illustrating a wafer, according to some embodiments. A wafer 102 in FIG. 1A may be divided into multiple dies 104. Each die 104 may include an integrated circuit, such as a chip. Typically, dies 104 may be cut from wafer 102 into individual dies 104 using a wafer saw. The individual dies 104 may be shipped to customers.

Prior to cutting the dies 104 from wafer 102, dies 104 may be electrically tested to identify good and defective dies. In a conventional approach, the defective dies may be marked with ink, as shown by die 104D, and then removed after wafer 102 is cut into dies 104. In addition to the defective dies, outlier detection tests may be performed on the dies to statistically identify progressively defective or failing dies. Progressively defective or failing dies may be dies that passed an electrical test, but are likely to fail in the field. Progressively defective or failing dies may also be marked with ink.

FIG. 1B is an exemplary diagram 100B of a digital wafer file, according to some embodiments. A digital wafer file 106 may track good and defective dies in wafer 102. To track good and defective dies, digital wafer file 106 may be aligned with wafer 102 and may include multiple digits 108 that correspond to locations of dies 104 in wafer 102. Each digit 108 may be set to an alphanumeric value or a symbol. The alphanumeric value may initially be set to a default value. Once an electrical test is executed for a particular die 104, the value may be set to indicate that die 104 is a good die or a defective die. In some embodiments, the default values may indicate good dies, and May be switched when the electric test indicates that that die 104 is a defective die. Once dies 104 of wafer 102 complete the electric test, and are marked as good dies or defective dies using digits 108 in the digital wafer file 106, the digital wafer file 106 may represent the good and defective dies 104 in wafer 102. In some embodiments, dies 104 that are identified as progressively defective dies may also be marked in digital wafer file 106, using the same or different alphanumeric value or a symbol as the defective dies.

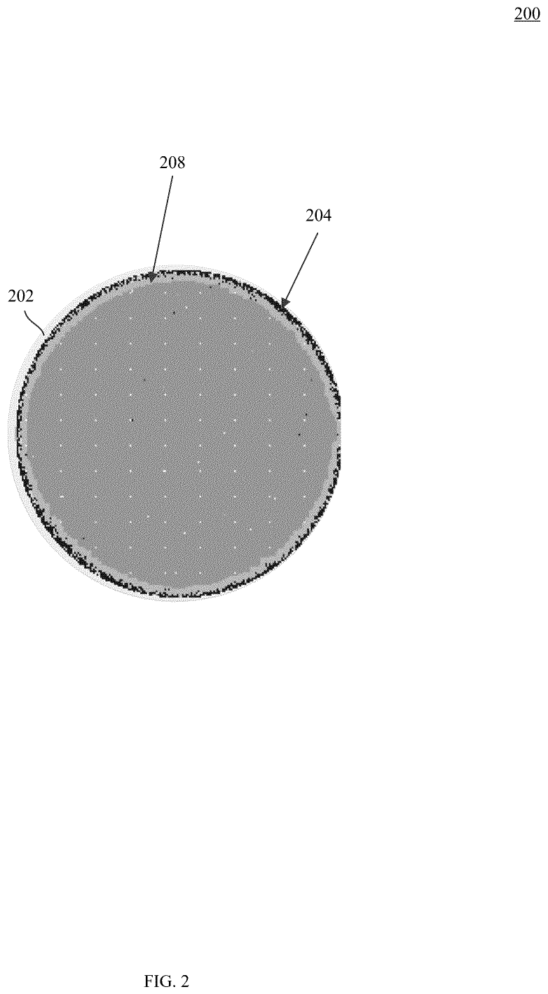

FIG. 2 is a diagram 200 illustrating a digital wafer map representing good and defective dies, according to some embodiments. A digital wafer map 202 in FIG. 2 may represent wafer 102 discussed in FIG. 1A or another wafer that has undergone electric testing on individual dies 104. The defective dies 104D may be illustrated as dies 204, that may be found around the edge of the wafer 102 or scattered throughout wafer 102.

As discussed above, conventional techniques may identify defective dies 204 that are then marked using ink on wafer 102 or in digital wafer map 202. Conventional techniques may also identify progressively failing dies that may have passed the electrical tests but have a high likelihood of failing in the future. Such dies may include dies that have an open via. Further, the conventional techniques may statistically predict progressively defective or failing dies and as a result be overinclusive. For example, a blanket in-out technique at a wafer edge can perform a blanket ink-out of dies 104 (shown as 208) a predefined distance from the edge the wafer 102. Such a technique dispose of good dies, which leads to an increased overall cost of manufacturing dies and a lower yield of good dies 104 from wafer 102.

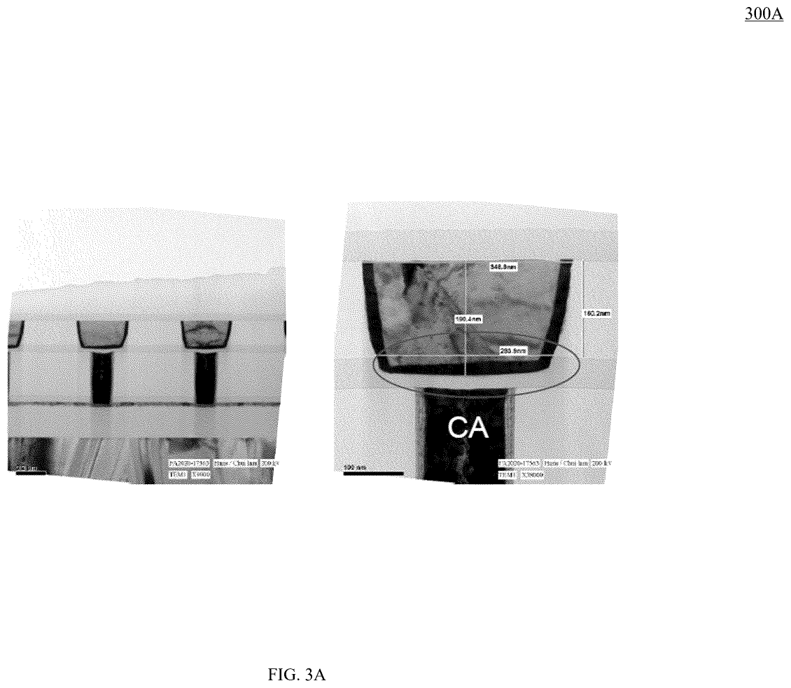

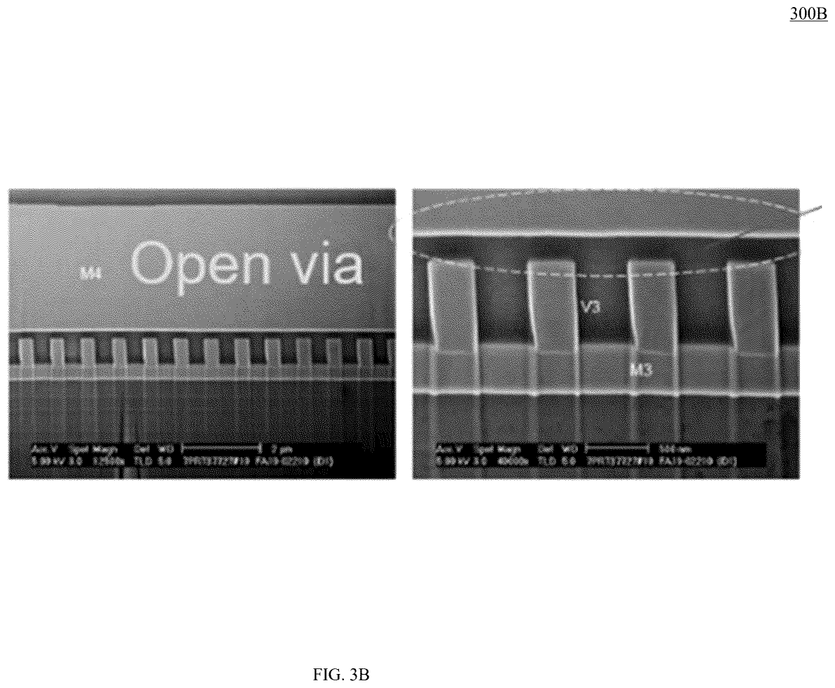

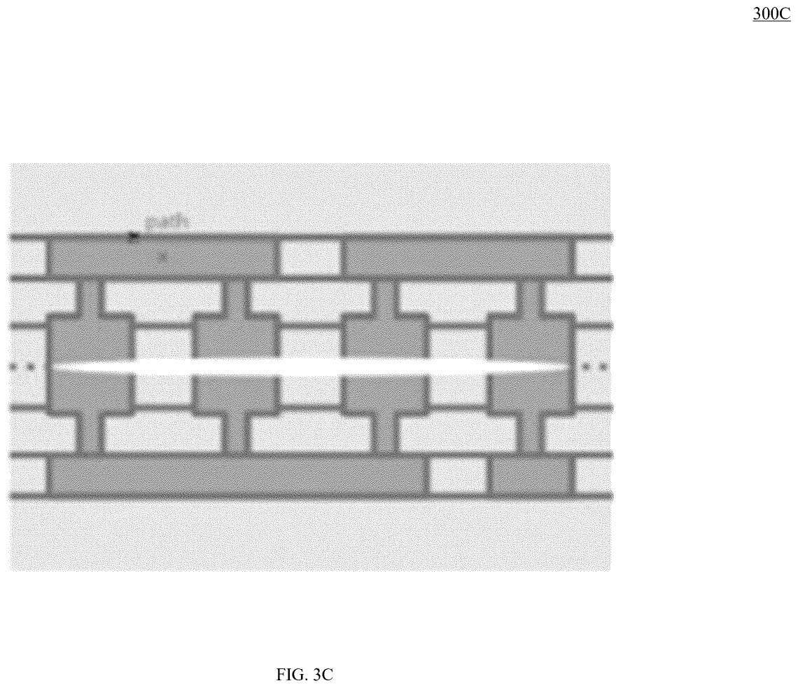

FIG. 3A is an example diagram 300A of an open via, according to some embodiments. FIG. 3A illustrates images of an example open via in an integrated circuit. FIG. 3B is another diagram 300B of open vias, according to some embodiments. FIG. 3B illustrates images of multiple open vias in the integrated circuit that may occur at a wafer edge. Notably, an integrated circuit may be defective when some vias are closed and other vias are open. If all vias on a circuit are open, the die may be identified as defective during testing. However, if some vias are open and other vias are closed, the die may pass testing, but may be a progressively failing die that may fail later in the field.

FIG. 3C is a diagram 300C of open vias show using a 3DIC stack, according to some embodiments. FIG. 3C illustrates a 3DIC stack that includes two open vias and two partially open vias. During testing, a die with these vias may pass the test due to the partially open vias, but may still fail in the field.

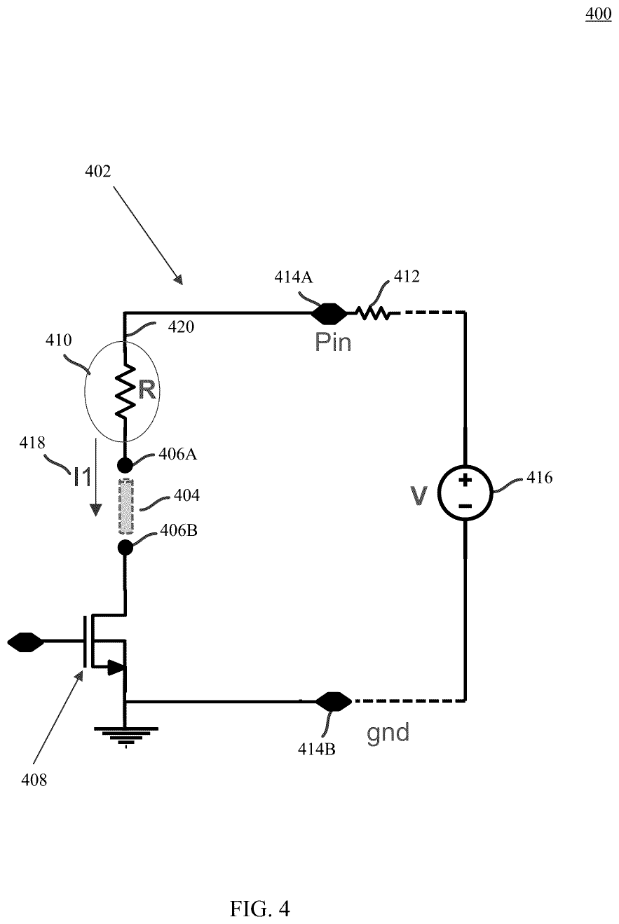

FIG. 4 is a diagram 400 of a DFM structure for detecting an open via, according to some embodiments. FIG. 4 illustrates a DFM structure 402 that may detect one or more open vias. DFM structure 402 may be incorporated into an integrated circuit of a die. Unlike conventional techniques, because DFM structure 402 is incorporated into each die, DFM structure 402 may identify a defective and progressively defective die on a granular level, such as on per die basis. It may also identify an integrity of vias on a granular basis, such as on a pair of vias basis. Accordingly, using DFM structure 402 to detect open vias within each die creates a greater die yield in a wafer, than conventional statistical or blanket-out techniques.

As discussed above, a via 404 is a hole that is filled with a conducive material, e.g., tungsten or copper, and may serve as an electrical connection between two or more layers in an integrated circuit. When open, via 404 may be unconnected to another layer or may be left unsealed, thus allowing signals to flow improperly through the integrated circuit. When via 404 is open, via 404 may lead to integrated circuit failures and loss of dies.

DFM structure 402 may determine an integrity of via 404 (shown as a single via) between pins 406A and 406B. DFM structure 402 may also determine integrity of a pair of vias in a stacked implementation of a wafer. Pins 406A and 406B may be metal layer pins. DFM structure 402 may also include a transistor 408, resistor 410, resistor 412, and pins 414A-B. Transistor 408 may be an n-MOSFET. Resistor 410 may have a predefined resistance. Resistor 412 may be external parasitic resistance. A voltage source 416 may be applied to pin 414A. Pin 414B may be a ground pin. Voltage source 416 may be a DC voltage. When transistor 408 is turned on, transistor 408 may have a resistance R₄₀₈.

DFM structure 402 may determine an integrity of a via 404 between pins 406A and 406B using current and voltage (IV) measurements to confirm resistance at branch 420 of DFM structure 402. In a test mode, voltage source 416 may be applied to pin 414A to measure current I1 418 through branch 420 when transistor 408 is turned on. The current I1 418 may be determined as follows:

$$I 1 = \frac{V}{{R}_{410} + {R}_{via} + {R}_{408}} \qquad Equation ( 1 )$$

where R₄₁₀ is the resistance at resistor 410, Rᵥᵢₐ is resistance at via 404 and R₄₀₈ is resistance at transistor 408. The resistance at branch 420 may be represented by resistance R1 that may be determined as follows:

$$R 1 = \frac{V}{I 1} = {R}_{410} + {R}_{via} + {R}_{408} \qquad Equation ( 2 )$$

The resistance of resistor 410 is a known value. Typically the value of resistor 410 is a high value that is above a predefined value threshold. The resistance Rᵥᵢₐ is typically negligible, such as Rᵥᵢₐ<<1Ω, for a good or heathy via 404, and is much higher for an open via 404. Accordingly, for a good via 404, resistance R₄₁₀˜ R1−R₄₀₈. However, for an open via, the resistance Rᵥᵢₐ would be much larger than 1Ω, which would cause the equation resistance R₄₁₀≈R1−R₄₀₈ to be false and prevent current I1 from flowing in branch 420. For example, suppose resistance of transistor 408 when it is turned on is R₄₀₈=100Ω, resistance at resistor 410 is R₄₁₀=20 kΩ, and resistance of a healthy via Rᵥᵢₐ=0.2Ω. As such, when source voltage 416 of 100 mV is applied to pin 414A, the current I1 would be as follows:

$$I 1 = \frac{100 mV}{1 \; 00 Ω + 20 k Ω + 0.2 Ω} \approx 5 μA$$

However, resistance Rᵥᵢₐ of an open via 404 would be much larger, and be in the order of G causing current I1 to be as follows:

$$I 2 = \frac{100 mV}{100 Ω + 20 k Ω + 1 G Ω} \approx 0.1 nA ≪ 5 μA$$

As such, DFM structure 402 would detect an open via when the current I1 418 is close to zero due to a large resistance Rᵥᵢₐ.

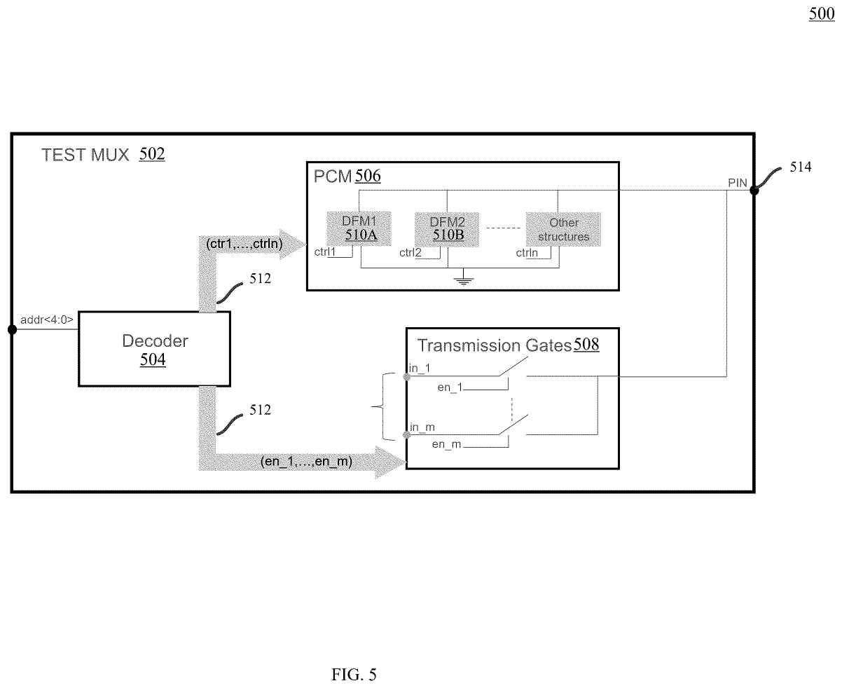

FIG. 5 is a block diagram of a test multiplexor in an integrated circuit of a die, according to some embodiment. FIG. 5 illustrates a test multiplexor or test mux 502 that is included in an integrated circuit of a die. Test mux 502 includes a decoder 504, a PCM 506, and transmission gates 508. Decoder 504 may receive control signals from the integrated circuit, decode the control signals, and transmit the control signals to either PCM 506 or transmission gates 508 via bus 512. Control signals may indicate whether PCM 506 or transmission gates 508 are turned on. When PCM 506 is turned on, control signals indicate which of the one or more DFM structures 510 are turned on as well.

PCM 506 may include one or more DFM structures 510, such as DFM structure 510A and 510B. DFM structures 510 may include circuitry for testing anomalies within the die. One of DFM structures 510 may include DFM structure 402 for detecting an open via. Other DFM structures 510 include different circuits, resistor values, etc., to detect other anomalies. The output of DFM structures 510 that indicates an anomaly may be measured at pin 514.

Transmission gates 508 may receive inputs that are voltage and/or current measurements from various blocks within the die. These current and voltage measurements may also be measured at pin 514.

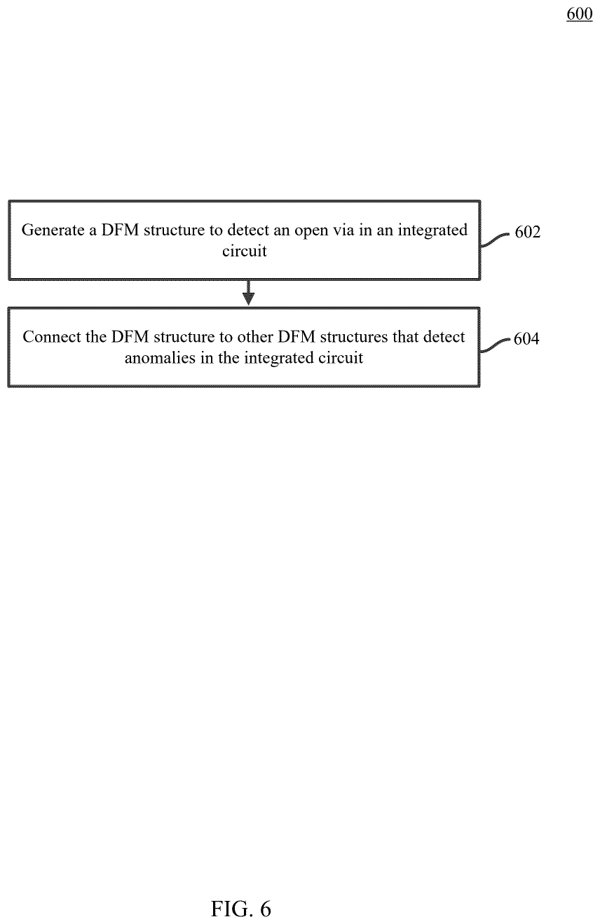

FIG. 6 is a flowchart of a method 600 for generating a DFM structure, according to some embodiments. Notably, method 600 is exemplary and other methods may also be used. Method 600 may be performed using hardware and/or software components described in FIGS. 1-5. Note that one or more of the operations may be deleted, combined, or performed in a different order as appropriate. Method 600 may be performed for each die 104 or a group of dies 104 in wafer 102.

At operation 602, a DFM structure is generated. For example, DFM structure 402 is generated in an integrated circuit to detect an open via. The DFM structure 402 may include resistor 410 and transistor 408 that has resistance R₄₀₈ when turned on. Additionally, DFM structure 402 may include pins 406A and 406B between which via 404 may be located.

At operation 604, a DFM structure is connected to other DFM structures. In some instances, DFM structure 402 may be included in PCM 506 of test mux 502, which may include other DFM structures 510 for detecting other anomalies in the integrated circuit of die 104. In this way, DFM structures 402 and other DFM structures 510 may be activated sequentially or in parallel to detect anomalies in the integrated circuit of die 104.

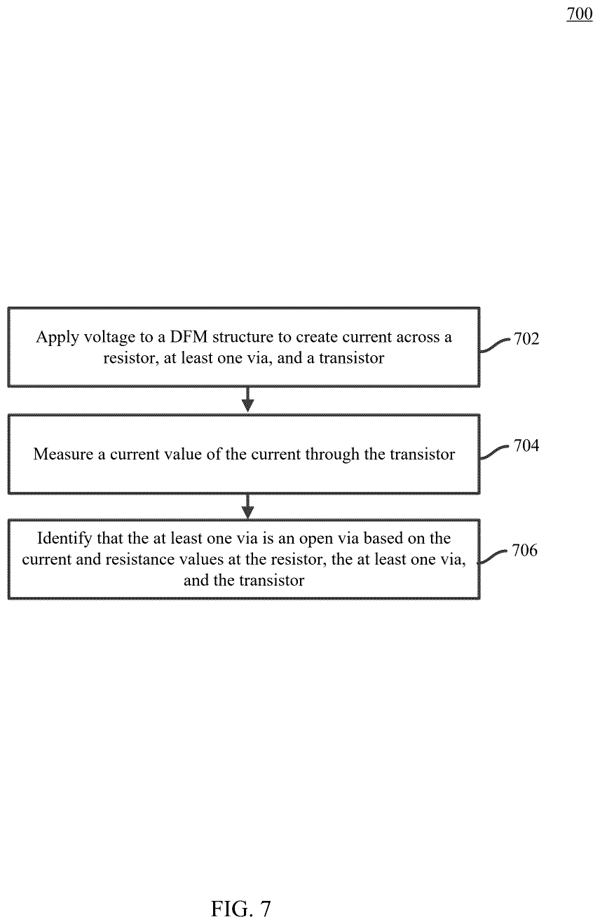

FIG. 7 is a flowchart of a method 700 for determining an open via, according to some embodiments. Notably, method 700 is exemplary and other methods may also be used. Method 700 may be performed using hardware and/or software components described in FIGS. 1-5. Note that one or more of the operations may be deleted, combined, or performed in a different order as appropriate.

At operation 702, a voltage is applied to the DFM structure. For example, voltage source 416 is applied to DFM structure 402 which creates current I1 across branch 420A and current I2 across branch 420B.

At operation 704, an open via is identified. For example, current I1 418 that flows in branch 420 may be determined by dividing the voltage by the resistance at branch 420. As discussed above, the resistance at branch 420 is a sum of resistance R₄₁₀ at resistor 410, resistance Rᵥᵢₐ across the via, and resistance R₄₀₈ at transistor 408. Since when via 404 is healthy or closed, the resistance Rᵥᵢₐ is negligible, current I1 418 would have one value. However, when via 404 is open, the resistance Rᵥᵢₐ is high, the current I1 418 may be small or negligible, which indicates open via 404 and an anomaly in the integrated circuit.

Where applicable, various embodiments provided by the disclosure may be implemented using hardware, software, or combinations of hardware and software. Also, where applicable, the various hardware components and/or software components set forth herein may be combined into composite components comprising software, hardware, and/or both without departing from the scope of the disclosure. Where applicable, the various hardware components and/or software components set forth herein may be separated into sub-components comprising software, hardware, or both without departing from the scope of the disclosure. In addition, where applicable, it is contemplated that software components may be implemented as hardware components and vice-versa.

Software, in accordance with the disclosure, such as program code and/or data, may be stored on one or more computer readable mediums. It is also contemplated that software identified herein may be implemented using one or more general purpose or specific purpose computers and/or computer systems, networked and/or otherwise. Where applicable, the ordering of various steps described herein may be changed, combined into composite steps, and/or separated into sub-steps to provide features described herein.

The foregoing disclosure is not intended to limit the disclosure to the precise forms or particular fields of use disclosed. As such, it is contemplated that various alternate embodiments and/or modifications to the disclosure, whether explicitly described or implied herein, are possible in light of the disclosure. Having thus described embodiments of the disclosure, persons of ordinary skill in the art will recognize that changes may be made in form and detail without departing from the scope of the disclosure. Thus, the disclosure is limited only by the claims.

What is claimed is:

1. A design for manufacturing (DFM) structure, comprising:
a resistor;
one or more vias between a first pin and a second pin;
a transistor; and
a voltage source configured to apply a voltage the DFM structure that causes a current to flow across the resistor, the one or more vias, and the transistor, wherein a value of the current indicates that the one or more vias are open or closed.

2. The DFM structure of claim 1, wherein the resistor and the transistor have known resistance values, and a resistance of one or more vias depends on the one or more vias being open or closed.

3. The DFM structure of claim 2, wherein the resistance of the one or more vias that are open is above a predefined threshold.

4. The DFM structure of claim 2, wherein the resistance of the one or more vias that are closed is a negligible resistance, wherein the negligible resistance is below a predefined threshold.

5. The DFM structure of claim 1, wherein the DFM structure is incorporated inside a process control monitor cell.

6. The DFM structure of claim 1, wherein a die with the one or more vias that are open is marked in an electronic wafer map that is aligned with a wafer.

7. The DFM structure of claim 1, wherein the resistor, the one or more vias, and the transistor are arranged in a sequence.

8. The DFM structure of claim 1, wherein the transistor is an n-MOSFET that is turned on when the voltage is applied to the DFM structure.

9. A process control monitor (PCM) cell comprising:
a plurality of DFM structures, wherein a DFM structure in the plurality of DFM structures is configured to identify a pair of vias that are open, the DFM structure comprising:
a resistor;
a pair of vias between a first pin and a second pin; and
a transistor; and
a voltage source configured to apply a voltage to the DFM structure that causes a current to flow across the resistor, the pair of vias and the transistor, wherein a value of the current indicates that the pair of vias are open.

10. The PCM cell of claim 9, wherein the resistor and the transistor have known resistance values and a resistance value of the pair of vias varies with the pair of vias being open or closed.

11. The PCM cell of claim 10, wherein the resistance value of the pair of vias that are opened is above a predefined value, wherein the predefined value is a mega ohm.

12. The PCM cell of claim 10, wherein the resistance value of the pair of vias that are closed is below a predefined value, wherein the predefined value is an ohm.

13. The PCM cell of claim 9, wherein the PCM cell is within an integrated circuit of a die.

14. The PCM cell of claim 9, wherein the resistor, the pair of vias, and the transistor are arranged in a sequence in the DFM structure.

15. A method, comprising:
applying a voltage to a DFM structure to create a current across a resistor, at least one component of a die having a component resistance, and a transistor having a transistor resistance; and
determining the at least one component is defective based on the current, the resistance at the resistor, the component resistance, and the transistor resistance.

16. The method of claim 15, wherein the at least one component has a negligible resistance when the at least one component is not defective, wherein the negligible resistance is less than a predefined ohm threshold.

17. The method of claim 15, wherein the at least one component has a high resistance when the at least one component is defective, wherein the high resistance is higher than a predefined threshold.

18. The method of claim 15, wherein the determining that the at least one component is defective is at a pin of a process control monitor cell, wherein the pin is coupled to the DFM structure.

19. The method of claim 15, wherein the resistor, the at least one component, and the transistor are arranged in a sequence.

20. The method of claim 15, wherein the DFM structure is within a test multiplexor of the die.
